(19) United States
(12) Patent Application Publication
(10) Pub. No.: US 2026/0072341 A1
(43) Pub. Date: Mar. 12, 2026

(54) OPTICAL PROXIMITY EFFECT CORRECTION METHOD FOR LAYOUT OF METAL LINES AND VIAS AND RELATED EQUIPMENT

(71) Applicant: SwaySure Technology Co., Ltd., Shenzhen (CN)

(72) Inventors: Yazhou REN, Shenzhen (CN); Yunghao CHEN, Shenzhen (CN); Chenxin MA, Shenzhen (CN); Xuefeng ZOU, Shenzhen (CN)

(21) Appl. No.: 19/268,489

(22) Filed: Jul. 14, 2025

(30) Foreign Application Priority Data
Sep. 10, 2024 (CN) 202411266755.6

(51) Int. Cl. G03F 1/36; G06F 30/3953

(52) U.S. Cl. CPC G03F 1/36; G06F 30/3953

(57) ABSTRACT

An optical proximity effect correction method for layout of metal lines and vias, includes: obtaining original layout of metal lines and vias; expanding each connection via in the width direction to form an enlarged connection via; translating each influencing metal line segment a certain distance away from the interconnection metal line along the width direction to form a preprocessed layout of metal lines and vias; and performing optical proximity correction on the preprocessed layout of metal lines and vias to obtain a corrected layout of metal lines and vias.

### CROSS-REFERENCE TO RELATED APPLICATIONS

This application claims priority to Chinese Patent Application No. 202411266755.6, filed on Sep. 10, 2024, the entire disclosure of which is hereby incorporated herein by reference.

### TECHNICAL FIELD

The present application relates to the technical field of semiconductor manufacturing, and particularly to an optical proximity effect correction method for layout of metal lines and vias, and a computer-readable storage medium.

### BACKGROUND

In the middle and back-end processes of semiconductor manufacturing, to form interconnection metals, vias need to be created between two metal lines of different layers to achieve interconnection metal. With the increase in circuit density, the reduction of critical dimensions, and the introduction of multi-patterning technology, the spacing between metal lines and the dimension of vias has become smaller and smaller, while the circuit density has become larger and larger. Especially for integrated circuits with a technology node below 50 nm, this easily leads to an excessively small lithography process window for metal lines, affecting product yield.

### SUMMARY

There are provided an optical proximity effect correction method for layout of metal lines and vias, and a computer-readable storage medium according to embodiments of the present application. The technical solution is as below:

According to a first aspect of embodiments of the present disclosure, there is provided an optical proximity correction method for layout of metal lines and vias, including:
obtaining an original layout of metal lines and vias, wherein the original layout of metal lines and vias comprises at least two metal line layers and a square via layer connecting metal lines in different layers, each metal line layer comprises an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line; and a metal line adjacent to the interconnection metal line along the width direction in the metal line layer is defined as an influencing metal line, and the influencing metal line comprises influencing metal line segment that refers to a projected line segment of the connection via on the influencing metal line along the width direction;
performing hole expansion processing on each connection via along the width direction to form an enlarged connection via, such that a dimension of the enlarged connection via along the width direction is greater than the width of the interconnection metal line, and a dimension of the enlarged connection via along the extension direction remains unchanged; and a dimension expansion amount of the connection via along the width direction is determined based on a current lithography process window;
performing translation processing on each influencing metal line segment along the width direction away from the interconnection metal line by a distance equal to the dimension expansion amount of the connection via along the width direction, to form a preprocessed layout of metal lines and vias; and
performing optical proximity correction on the preprocessed layout of metal lines and vias to obtain a corrected layout of metal lines and vias.

According to a second aspect of embodiments of the present disclosure, there is provided a computer-readable storage medium, wherein the computer-readable storage medium stores a computer program adapted to be loaded by a processor to execute the method as mentioned above.

### BRIEF DESCRIPTION OF THE DRAWINGS

To more clearly illustrate the technical solutions in the embodiments of the present application, the following briefly introduces the drawings required for describing the embodiments. Obviously, the drawings described below are only some embodiments of the present application, and those skilled in the art can obtain other drawings based on these drawings without creative efforts.

FIG. 1 is a flowchart of an optical proximity effect correction method for layout of metal lines and vias provided in an embodiment of the present application.

FIG. 2 is a schematic cross-sectional structure diagram of an original layout of metal lines and vias provided in an embodiment of the present application.

FIG. 3 is a schematic top-view structure diagram of a square via layer and a second metal line layer in FIG. 2.

FIG. 4 is a schematic bottom-view structure diagram of a first metal line layer and a square via layer in FIG. 2.

FIG. 5 is a schematic top-view structure diagram after hole expansion processing of connection vias provided in an embodiment of the present application.

FIG. 6 is a schematic top-view structure diagram after translation of influencing metal line segments provided in an embodiment of the present application.

FIG. 7 is another schematic cross-sectional structure diagram of an original layout of metal lines and vias provided in an embodiment of the present application.

FIG. 8 is a schematic top-view structure diagram of a first square via layer, a second metal line layer, and a second square via layer in FIG. 7.

FIG. 9 is another schematic top-view structure diagram after hole expansion processing of connection vias provided in an embodiment of the present application.

FIG. 10 is another schematic top-view structure diagram after translation of influencing metal line segments provided in an embodiment of the present application.

FIG. 11 is a schematic structural diagram of an optical proximity effect correction device for layout of metal lines and vias provided in an embodiment of the present application.

### DETAILED DESCRIPTION OF THE EMBODIMENTS

The following will clearly and completely describe the technical solutions in the embodiments of the present application with reference to the drawings in the embodiments of the present application. Obviously, the described embodiments are only a part of the embodiments of the present application, rather than all embodiments. Based on the embodiments in the present application, all other embodiments obtained by those skilled in the art without creative efforts shall fall within the protection scope of the present application.

In the following description, specific embodiments of the present application will be described with reference to steps and symbols executed by one or more computers, unless otherwise specified. Therefore, these steps and operations will be repeatedly mentioned to be executed by a computer, where “computer execution” as used herein includes operations of a computer processing unit representing electronic signals of data in a structured form. This operation transforms the data or maintains it in a position in the computer's memory system, which can reconfigure or otherwise change the computer's operations in a manner well-known to those skilled in the art. The data structure maintained by the data is a physical location in the memory having specific characteristics defined by the data format. However, the principles of the present application are described in the above words and are not intended to be limiting, as those skilled in the art will appreciate that the various steps and operations described below can also be implemented in hardware.

The terms “module” or “unit” used herein may be regarded as software objects executing on the computing system. The different components, modules, engines, and services described herein may be regarded as implementing objects on the computing system. The devices and methods described herein are preferably implemented in software, but may of course also be implemented in hardware, all within the protection scope of the present application.

In the following description of the present application, reference to “some embodiments” describes a subset of all possible embodiments, but it can be understood that “some embodiments” may be the same subset or different subsets of all possible embodiments, and may be combined with each other without conflict.

In the following description of the present application, the terms “first\second\third” are only used to distinguish similar objects and do not represent a specific ordering for the objects. It can be understood that “first\second\third” may interchange specific orders or sequences where permitted, so that the embodiments of the present application described herein can be implemented in an order other than that illustrated or described herein.

Additionally, directional terms mentioned in the present application, such as [upper], [lower], [front], [rear], [left], [right], [inner], [outer], [side], etc., are only referenced to the directions in the attached drawings. Therefore, the directional terms used are for explaining and understanding the present application, rather than limiting the present application. In the various drawings, structurally similar units are denoted by the same reference numerals. For clarity, the various parts in the drawings are not drawn to scale. Additionally, some well-known parts may not be shown in the drawings.

Unless otherwise defined, all technical and scientific terms used herein have the same meaning as commonly understood by those skilled in the technical field of the present application. The terms used herein are only for the purpose of describing the embodiments of the present application and are not intended to limit the present application.

An embodiment of the present application provides an optical proximity effect correction method for layout of metal lines and vias. First, connection vias that connect metal lines located in different layers, and the interconnection metal lines, influencing metal lines, and influencing metal line segments corresponding to the connection vias, are identified from the original layout of metal lines and vias. The interconnection metal lines refer to the metal lines connected to the connection vias; the influencing metal lines refer to the metal lines adjacent to the interconnection metal lines along the width direction (the width direction is a direction perpendicular to the extension direction of the interconnection metal lines within the plane of the metal line layer where the interconnection metal lines are located); and the influencing metal line segments refer to the projection region line segments of the connection vias on the influencing metal lines along the width direction. Then, the connection vias are subjected to hole expansion along the width direction to form enlarged connection vias, thereby increasing the lithography process window for the interconnection metal lines and connection vias, and the influencing metal line segments are translated by a certain distance along the width direction away from the interconnection metal lines, this distance is made to be equal to the dimension expansion amount of the connection vias along the width direction, to reduce the occurrence of bridge defects between the interconnection metal lines and adjacent metal lines, while simultaneously reducing defects such as necking and open circuits in the influencing metal line segments due to excessive movement. Subsequently, the optical proximity correction method is used to correct the enlarged connection vias and the moved interconnection metal lines, thereby expanding the lithography process window on the basis of satisfying circuit conduction.

Compared with the related optical proximity effect correction method for layout of metal lines and vias, which first globally enlarges vias, reduces the dimension of interconnection metal lines, and then uses an OPC model to correct the globally enlarged connection vias and reduced interconnection metal lines to expand the lithography process window on the basis of satisfying circuit conduction, such that enlargement of adjacent vias easily causes via bridge defects; reduction of interconnection metal lines easily leads to electromigration, causing local thinning (necking) defects in the interconnection metal lines; and subjected to processes such as etching and chemical mechanical polishing (CMP), the risk of open circuits in interconnection metal lines is increased. However, the embodiment of the present application enlarges vias and appropriately moves related influencing metal line segments without reducing the dimension of interconnection metal lines, such that it not only increases the lithography process window for interconnection metal lines and vias but also reduces bridge defects in interconnection metal lines, and due to avoiding dimension reduction of interconnection metal lines, it can avoid the problem of local thinning (necking) defects caused by electromigration in reduced interconnects and the risk of open circuits due to processes like etching and CMP, thereby improving product yield.

Compared with related solutions that merging adjacent vias to increase via dimension for addressing the issue of too small lithography process windows in conventional subsequent OPC corrections, such solutions require the original layout of metal lines and vias to satisfy preconditions (e.g., there are two vias in the same layer and close to each other; the devices to which the two vias belong have consistent functions and do not affect the interconnection circuit). These preconditions limit the applicability of such solutions and reduce their generality for layout of metal lines and vias. In contrast, the optical proximity effect correction method for layout of metal lines and vias in the embodiments of the present application not only solves the problem of too small lithography process windows in conventional OPC corrections but also has good generality for layout of metal lines and vias, offering broad application prospects.

The following details are described in conjunction with specific embodiments, noting that the sequence numbers of the following embodiments do not limit the priority order of the embodiments.

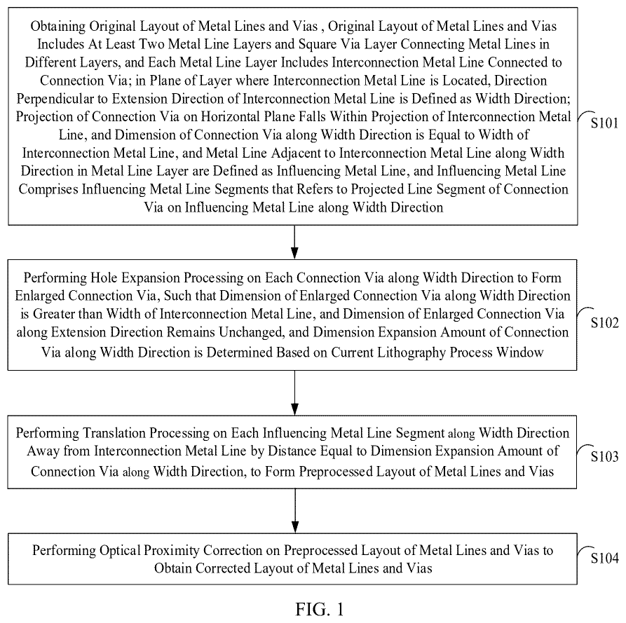

Refer to FIG. 1, which is a schematic flow diagram of an optical proximity effect correction method for layout of metal lines and vias provided in an embodiment of the present application. The method can be executed by an optical proximity effect correction device for layout of metal lines and vias and applied to the scenario of optically proximity correcting an original layout of metal lines and vias (i.e., the layout of metal lines and vias requiring optical proximity effect correction, which is the layout of metal lines and vias obtained after actual fabrication processes based on the design). The method first identifies, from the original layout of metal lines and vias, connection vias that connect metal lines in different layers, and the interconnection metal lines, influencing metal lines, and influencing metal line segments corresponding to the connection vias. Then, the connection vias are enlarged, and the corresponding influencing metal line segments are appropriately moved to form a preprocessed layout of metal lines and vias. Subsequently, conventional optical proximity correction methods are used to correct the preprocessed layout of metal lines and vias to obtain a corrected layout of metal lines and vias, which can be used to fabricate corresponding metal line and via mask plates. The metal line and via patterns in the corrected layout of metal lines and vias are consistent with those on the corresponding metal line and via mask plates. The specific process of the method may be as follows:

S101. obtaining an original layout of metal lines and vias, wherein the original layout of metal lines and vias includes at least two metal line layers and a square via layer connecting metal lines in different layers, and each metal line layer includes an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line, and a metal line adjacent to the interconnection metal line along the width direction in the metal line layer is defined as an influencing metal line, and the influencing metal line comprises influencing metal line segments that refers to a projected line segment of the connection via on the influencing metal line along the width direction.

In this embodiment, in the original layout of metal lines and vias, each metal line layer may include at least one metal line, there may be one or more layers of square vias, each square via layer may include at least one square via, and a cross-section of the square via may be square or rectangular.

Specifically, in the original layout of metal lines and vias, there may be one or more connection vias, and the connection vias belong to the square via layer. Each connection via is specifically a square via that is in a square via layer where it locates and that connects metal lines located in different layers.

Specifically, in the original layout of metal lines and vias, for each connection via, the metal line in each metal line layer and connected to the connection via is the interconnection metal line corresponding to the connection via; in the plane of the metal line layer where the interconnection metal line corresponding to the connection via is located, the direction perpendicular to the extension direction of the interconnection metal line corresponding to the connection via is the width direction corresponding to the connection via; the projection of the connection via on the horizontal plane is within the projection of the interconnection metal line corresponding to the connection via on the horizontal plane, and the dimension of the connection via in its corresponding width direction is equal to the width of its corresponding interconnection metal line; in each metal line layer, the metal lines adjacent to the interconnection metal line corresponding to the connection via along the width direction corresponding to the connection via are the influencing metal lines corresponding to the connection via; the projection region line segment of the connection via along its corresponding width direction on the influencing metal line is the influencing metal line segment corresponding to the connection via.

In specific implementation, after obtaining the original layout of metal lines and vias, all connection vias and their corresponding interconnection metal lines, width directions, influencing metal lines, and influencing metal line segments can be identified from the obtained original layout of metal lines and vias to facilitate subsequent processing of the obtained original layout of metal lines and vias.

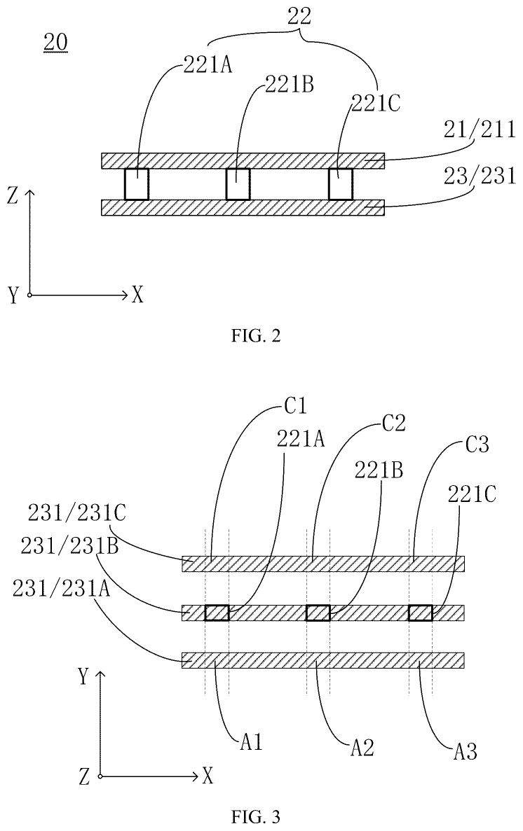

For ease of understanding, a specific explanation is provided below using the original layout of metal lines and vias 20 shown in FIG. 2. As shown in FIG. 2, the original layout of metal lines and vias 20 may include two metal line layers (i.e., the first metal line layer 21 and the second metal line layer 23) and a square via layer (i.e., the first square via layer 22) connecting the metal line 211 in the first metal line layer 21 and the metal line 231 in the second metal line layer 23. The first square via layer 22 includes three connection vias (i.e., connection vias 221A, 221B, and 221C), each connection via is used to connect the metal line 211 in the first metal line layer 21 with the metal line 231 in the second metal line layer 23.

Further, as shown in FIG. 3, observing the first square via layer 22 and the second metal line layer 23 from a top view, the second metal line layer 23 includes three metal lines 231 (i.e., the first metal line 231A, the second metal line 231B, and the third metal line 231C). In the second metal line layer 23, the interconnection metal line corresponding to the connection via 221A is the metal line 231B, the corresponding width direction is parallel to the Y-axis in FIG. 3, there are two corresponding influencing metal lines: the metal lines 231A and 231C, and there two corresponding influencing metal line segments: the metal line segment A1 included in metal line 231A and the metal line segment C1 included in metal line 231C. The interconnection metal line corresponding to the connection via 221B is the metal line 231B, the width direction corresponding to the connection via 221B is parallel to the Y-axis in FIG. 3, there are two corresponding influencing metal lines: metal lines 231A and 231C, and there are two corresponding influencing metal line segments: the metal line segment A2 included in the metal line 231A and the metal line segment C2 included in the metal line 231C. The interconnection metal line corresponding to the connection via 221C is the metal line 231B, the corresponding width direction is parallel to the Y-axis in FIG. 3, there are two influencing metal lines: metal lines 231A and 231C, and there are two influencing metal line segments: the metal line segment A3 included in the metal line 231A and the metal line segment C3 included in the metal line 231C.

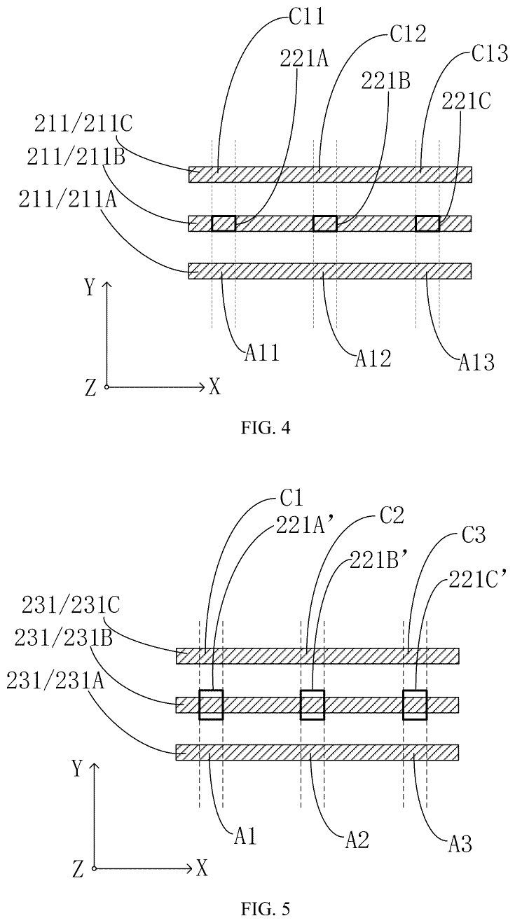

Further, as shown in FIG. 4, observing the first metal line layer 21 and the first square via layer 22 from a bottom view, the first metal line layer 21 includes three metal lines 211 (i.e., the first metal line 211A, the second metal line 211B, and the third metal line 211C). In the first metal line layer 21, the interconnection metal line corresponding to the connection via 221A is metal line 211B, the corresponding width direction is parallel to the Y-axis in FIG. 4, there are two corresponding influencing metal lines: metal lines 211A and 211C, and there are two corresponding influencing metal line segments: the metal line segment A11 included in the metal line 211A and the metal line segment C11 in metal line 211C. The interconnection metal line corresponding to the connection via 221B is the metal line 211B, the corresponding width direction is parallel to the Y-axis in FIG. 4, there are two corresponding influencing metal lines: metal lines 211A and 211C, and there are two corresponding influencing metal line segments: metal line segment A12 included in the metal line 211A and metal line segment C12 included in the metal line 211C. The interconnection metal line corresponding to the connection via 221C is the metal line 211B, the corresponding width direction is parallel to the Y-axis in FIG. 4, there are two influencing metal lines: metal lines 211A and 211C, and there are two corresponding influencing metal line segments: metal line segment A13 included in the metal line 211A and metal line segment C13 included in the metal line 211C.

It should be noted that, as shown in FIG. 4, in this embodiment, the projection of each connection via (e.g., connection vias 221A, 221B, 221C) on the horizontal plane (i.e., the plane parallel to the X and Y axes in FIG. 4) is within the projection of its corresponding interconnection metal line 211B on the horizontal plane, and the dimension of each connection via (e.g., connection vias 221A, 221B, 221C) in its corresponding width direction (i.e., the direction parallel to the Y-axis in FIG. 4) is equal to the width of its corresponding interconnection metal line 211B. The width-direction dimension of the connection via is controlled to be small while maximizing the contact area of the metal connection plug filled in the connection via with the interconnection metal line, achieving good interconnection performance.

It can be understood that FIG. 2 does not fully display all metal line layers and square via layers in the original layout of metal lines and vias, but only a part of them, sufficient to illustrate the present application. Of course, the original layout of metal lines and vias may also include only the metal line layers and square via layers shown in FIG. 2.

In some embodiments, in the original layout of metal lines and vias, for each metal line layer, all metal lines in the metal line layer may be arranged in a regular pattern, for example, all metal lines in the metal line layer may be arranged in an overall periodic pattern. Specifically, all metal lines in the metal line layer may extend in only two directions: horizontal and vertical, where the horizontal and vertical directions are parallel to the metal line layer and perpendicular to each other. Alternatively, all metal lines in the metal line layer may be arranged irregularly, such as all metal lines in the metal line layer may be arranged in a disordered state, all metal lines in the metal line layer have multiple and irregular extension directions.

In some embodiments, for each metal line layer in the original layout of metal lines and vias, all metal line patterns in the metal line layer may be designed to be transferred through one or more lithography processes. It can be understood that metal line patterns in the metal line layer is designed to be transferred through multiple lithography processes to make the metal line layer suitable for Multi-Patterning technology.

S102. performing hole expansion processing on each connection via along the width direction to form an enlarged connection via, such that a dimension of the enlarged connection via along the width direction is greater than the width of the interconnection metal line, and a dimension of the enlarged connection via along the extension direction remains unchanged, and a dimension expansion amount of the connection via along the width direction is determined based on a current lithography process window.

Specifically, for each connection via in the original layout of metal lines and vias, hole expansion processing is performed on the connection via in its corresponding width direction to form a corresponding enlarged connection via, and the dimension of the enlarged connection via corresponding to the connection via along the width direction corresponding to the connection via is greater than the width of the interconnection metal line corresponding to the connection via, and the dimension of the enlarged connection via corresponding to the connection via along the extension direction of the interconnection metal line corresponding to the connection via is equal to the dimension of the connection via along the extension direction of its corresponding enlarged connection via. In other words, enlarging the connection via only increases its dimension in the its corresponding width direction without changing its dimension along the extension direction of its corresponding interconnection metal line.

Moreover, the inventors of the present application have found that increasing the dimension of the connection via along the extension direction of its corresponding interconnection metal line has no significant effect on expanding the lithography process window of the connection via and the interconnection metal line, but may cause excessive dimension of the enlarged connection via to waste filling materials and prone to bridging defects in the enlarged connection via. Therefore, in this embodiment, by only increasing the dimension of the connection via in its corresponding width direction while keeping the dimension of the connection via along the extension direction of its corresponding interconnection metal line unchanged, which not only can expand the lithography process window of the connection via and the interconnection metal line, but also can reduce the operational difficulty of hole expansion processing for the connection via, and can avoid waste of filling materials due to excessively large connection vias, and can minimize the risk of bridging in the enlarged connection vias.

Specifically, for each connection via, the dimension of the connection via in its corresponding width direction may specifically be one of the width and length of the connection via, and the dimension of the connection via along the extension direction of its corresponding interconnection metal line may specifically be the other of the width and length of the connection via.

In this embodiment, for each connection via, the difference between the dimension of the enlarged connection via corresponding to the connection via along the width direction corresponding to the connection via and the dimension of the connection via in its width direction is equal to the dimension expansion amount of the connection via in its width direction. The dimension expansion amount of the connection via in its corresponding width direction is determined according to the current lithography process window.

It can be understood that in lithography, the lithography process window is a critical criterion for measuring lithography performance, and relevant researchers have always been committed to optimizing the lithography process window to achieve a larger window. The lithography process window may refer to the range of exposure dose and defocus amount that ensures the correct transfer of mask patterns to the wafer, including three aspects of information: imaging accuracy, exposure dose, and depth of focus.

Specifically, the current lithography process window in this embodiment may refer to the range of exposure dose and defocus amount that ensures the correct transfer of metal line and via patterns in the original layout of metal lines and vias to the wafer. The dimension expansion amount of the connection via in its corresponding width direction can be determined according to the current lithography process window, which means that the dimension expansion amount of the connection via in its corresponding width direction should ensure that the formed enlarged connection via can be correctly transferred to the wafer under the current lithography process window, i.e., without defects such as bridging or overlap.

In specific implementation, the dimension expansion amount of the connection via in its corresponding width direction may be less than or equal to the alignment margin. The alignment margin refers to the maximum allowable offset when transferring the metal line pattern of the upper metal line layer over a layer where the connection via locates through lithography process. It can be understood that the upper metal line layer can be correctly transferred only if the offset when transferring the metal line pattern of the upper metal line layer over a layer where the connection via locates through lithography process is not greater than the maximum allowable offset; otherwise, the upper metal line layer cannot be correctly transferred if the offset when transferring the metal line pattern of the upper metal line layer over a layer where the connection via locates through lithography process is greater than the maximum allowable offset.

In some embodiments, the ratio of the dimension expansion amount of each connection via in its corresponding width direction to the dimension of the connection via in its width direction may be α, where 0.5≤α≤0.75. For example, α may be 0.5, 0.55, 0.6, 0.65, 0.7, or 0.75, such that it can ensure a moderate dimension expansion amount for the connection via 221, expanding the lithography process window of the connection via and interconnection metal line while reducing the risk of bridging or overlap of the interconnection metal line under the expanded lithography process window.

In some specific embodiments, the above performing the hole expansion processing on the connection via along the width direction to form an enlarged connection via may specifically includes: expanding the connection via by a first dimension expansion amount and a second dimension expansion amount toward both sides of the interconnection metal line along the width direction, where a sum of the first and second dimension expansion amounts equals the dimension expansion amount of the connection via.

Specifically, for each connection via in the original layout of metal lines and vias, hole expansion processing is performed toward both sides of its corresponding interconnection metal line along the width direction by the first and second dimension expansion amounts, respectively. The sum of the first and second dimension expansion amounts equals the dimension expansion amount of the connection via in its width direction. The spacing distances between the two opposite sides of the corresponding enlarged connection via along the width direction corresponding to the connection via and the connection via are equal to the first and second dimension expansion amounts, respectively. In practice, the first and second dimension expansion amounts may be equal to achieve same dimension outward expansion of the two opposite sides of the connection via along its width direction, thereby improving the electrical uniformity of the interconnection metal structure.

For ease of understanding, taking the three connection vias (that is, connection vias 221A, 221B, and 221C) in the original layout of metal lines and vias 20 shown in FIG. 3 as an example. As shown in FIGS. 3 and 5, after hole expansion processing of the connection via 221A in its corresponding width direction, it becomes enlarged connection via 221A′; after hole expansion processing of the connection via 221B in its corresponding width direction, the connection via 221B becomes the enlarged connection via 221B′, after hole expansion processing of the connection via 221C in its corresponding width direction, and the connection via 221C becomes enlarged connection via 221C′.

S103, performing translation processing on each influencing metal line segment along the width direction away from the interconnection metal line by a distance equal to the dimension expansion amount of the connection via along the width direction, to form a preprocessed layout of metal lines and vias.

Specifically, for each connection via in the original layout of metal lines and vias, after performing the hole expansion processing on the connection via in its corresponding width direction to form an enlarged connection via, the corresponding influencing metal line segment is then translated along the width direction corresponding to the connection via away from the interconnection metal line corresponding to the connection via by a distance equal to the spacing distance between the target edge of the corresponding enlarged connection via and the connection via. The target edge refers to the edge opposite to the influencing metal line segment corresponding to the connection via along the width direction corresponding to the connection via. In this way, after expanding the connection via to enlarge the lithography process window of the interconnection metal line and the connection via, the influencing metal line segment is further translated by a corresponding distance, which not only prevents the enlarged connection via from overlapping with the influencing metal line segment, but also reduces the risk of bridging between the interconnection metal lines under the expanded process window.

In some embodiments, to avoid breakage of the influencing metal line caused by translation of the influencing metal line segment belonging to the influencing metal line, a maximum allowable translation distance for the influencing metal line segment may be set to ensure that the translation distance of the metal line when translating is less than or equal to the maximum allowable distance. For example, the maximum allowable translation distance of the influencing metal line segment may be less than or equal to ½ to ¾ of the width of the influencing metal line to which the metal line segment belongs.

In some embodiments, in the same metal line layer, an interconnection metal line may have one influencing metal line on each side, referred to as the first influencing metal line and the second influencing metal line. Correspondingly, performing hole expansion processing on the connection via connected to the interconnection metal line in its width direction may specifically includes: expanding the connection via connected to the interconnection metal line by a first dimension expansion amount toward the first influencing metal line and a second dimension expansion amount toward the second influencing metal line in its width direction.

Correspondingly, the translation distance of the influencing metal line segment of the first influencing metal line may be a first translation distance, and the translation distance of the second influencing metal line may be a second translation distance. The first translation distance is equal to the first dimension expansion amount during hole expansion processing of the connection via connected to the interconnection metal line, and the second translation distance is equal to the second dimension expansion amount during hole expansion processing of the connection via connected to the interconnection metal line.

For ease of understanding, taking the second metal line layer 23 in the original layout of metal lines and vias 20 shown in FIG. 2 as an example. As shown in FIGS. 2 and 3, in the second metal line layer 23, the interconnection metal line 231B has a first influencing metal line 231A and a second influencing metal line 231C on both sides. First, as shown in FIGS. 3 and 5, the connection via 221A connected to the interconnection metal line 231B is expanded toward the first influencing metal line 231A and the second influencing metal line 231C by the first and second dimension expansion amounts in its width direction to form an enlarged connection vias 221A′. The connection via 221B connected to the interconnection metal line 231B is expanded toward the first influencing metal line 231A and the second influencing metal line 231C by the first and second dimension expansion amounts in its width direction to form an enlarged connection via 221B′. The connection via 221C connected to the interconnection metal line 231B is expanded toward the first influencing metal line 231A and the second influencing metal line 231C by the first and second dimension expansion amounts in its width direction to form an enlarged connection via 221C′.

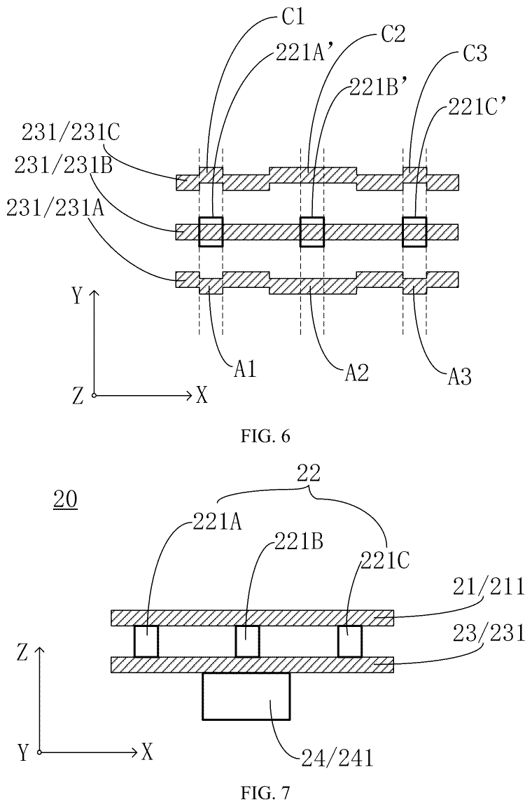

Subsequently, as shown in FIGS. 3, 5, and 6, the influencing metal line segment A1 corresponding to the connection via 221A in the first influencing metal line 231A is translated along the width direction corresponding to the connection via 221A away from the interconnection metal line 231B by a distance equal to the first dimension expansion amount of the connection via 221A during the edge expansion processing of the connection via 221A. The influencing metal line segment A2 corresponding to the connection via 221B in the first influencing metal line 231A is translated along the width direction corresponding to the connection via 221B away from the interconnection metal line 231B by a distance equal to the first dimension expansion amount of the connection via 221B during the edge expansion processing of the connection via 221B. The influencing metal line segment A3 corresponding to the connection via 221C in the first influencing metal line 231A is translated along the width direction corresponding to the connection via 221B away from the interconnection metal line 231B by a distance equal to the first dimension expansion amount of the connection via 221C during the edge expansion processing of the connection via 221C. The influencing metal line segment C1 corresponding to the connection via 221A in the second influencing metal line 231C is translated along the width direction corresponding to the connection via 221A away from the interconnection metal line 231B by a distance equal to the second dimension expansion amount of the connection via 221A during the edge expansion processing of the connection via 221A. The influencing metal line segment C2 corresponding to the connection via 221B in the second influencing metal line 231C is translated along the width direction corresponding to the connection via 221B away from the interconnection metal line 231B by a distance equal to the second dimension expansion amount of the connection via 221B during the edge expansion processing of the connection via 221B. The influencing metal line segment C3 corresponding to the connection via 221C in the second influencing metal line 231C is translated along the width direction corresponding to the connection via 221C away from the interconnection metal line 231B by a distance equal to the second dimension expansion amount of the connection via 221C during the edge expansion processing of the connection via 221C.

In some embodiments, in the same metal line layer, upper surface and lower surface of an interconnection metal line may be connected to two connection vias (i.e., a first connection via and a second connection via). The projection of the first connection via on the horizontal plane overlaps with that of the second connection via on the horizontal plane. The dimension of the first connection via in its corresponding width direction may be the same as that of the second connection via in its corresponding width direction, for example, may be equal to the width of the interconnection metal line. The dimension of the first connection via along the extension direction of the interconnection metal line may be smaller than that of the second connection via along the extension direction of the interconnection metal line.

The edge expansion processing for the first and second connection vias to form enlarged connection vias may include: expanding the first connection via in its width direction to form a first enlarged connection via; expanding the second connection via in its width direction to form a second enlarged connection via, where the dimension expansion amount of the first connection via in its width direction is greater than that of the second connection via in its width direction.

In some specific embodiments, when performing edge expansion processing, a ratio β of the dimension expansion amount of the second connection via to that of the first connection via may satisfy 0.4≤β≤0.8, e.g., β can be 0.4, 0.45, 0.5, 0.55, 0.6, 0.65, 0.7, 0.75, or 0.8. In this way, it ensures moderate dimension expansion amounts for both the first and second connection vias connected to the upper and lower surfaces of the same interconnection metal line.

In some specific embodiments, when the upper and lower surfaces of the interconnection metal line are connected to the first connection via and the second connection via, respectively, and in the metal line layer where the interconnection metal line locates, the influencing metal line segments corresponding to the first and second connection vias may include a first-region influencing metal line segment, a second-region influencing metal line segment, and a third-region influencing metal line segment. The first-region influencing metal line segment is an overlapping projection region line segment of both the first and second connection vias on the their influencing metal lines along their width directions. The second-region influencing metal line segment is the projection region line segment of only the first connection via on the its influencing metal line along its width directions; and the third-region influencing metal line segment is the projection region line segment of only the second connection via on the its influencing metal line along its width direction. In other words, the first-region influencing metal line segment not only belongs to the influencing metal line segment corresponding to the first connection via, but also belongs to the influencing metal line segment corresponding to the second connection via. The second-region influencing metal line segment belongs only to the influencing metal line segment corresponding to the first connection via, not belong to the influencing metal line segment corresponding to the second connection via, and the third-region influencing metal line segment belongs only to the influencing metal line segment corresponding to the second connection via, but does not belong to the influencing metal line segment corresponding to the first connection via.

Correspondingly, translating the influencing metal line segments corresponding to the first connection via and the second connection via may specifically include: translating the first-region influencing metal line segments, the second-region influencing metal line segments, and the third-region influencing metal line segments in their respective width directions (i.e., the directions perpendicular to the extension directions of the interconnection metal lines whose the upper surface and the lower surface connect the first connection via and the second connection via, respectively) by a certain distance away from the corresponding interconnection metal lines (i.e., the interconnection metal lines whose the upper surface and the lower surface connect the first connection via and the second connection via, respectively). The translation distance of the first-region influencing metal line segment is equal to the sum of the dimension expansion amount of the first connection via during the edge expansion processing and the dimension expansion amount of the second connection via during the edge expansion processing. The translation distance of the second-region influencing metal line segments is equal to the dimension expansion amount of the first connection via during the edge expansion processing. The translation distance of the third-region influencing metal line segments is equal to the dimension expansion amount of the second connection via during the edge expansion processing.

Specifically, performing edge expansion processing on the first connection via and the second connection via respectively may specifically include: performing hole expansion processing on the first connection via in its corresponding width direction toward both sides (i.e., the first side and the second side) of the corresponding interconnection metal line by a first expansion amount and a second expansion amount respectively; performing hole expansion processing on the second connection via in its corresponding width direction toward both sides of the corresponding interconnection metal line by a first expansion amount and a second expansion amount respectively. Correspondingly, in the metal line layer where the corresponding interconnection metal line is located, for the influencing metal line segments corresponding to the first connection via and the second connection via: the movement distance during translation of the first-region influencing metal line segments located on the first side of the corresponding interconnection metal line included in the influencing metal line segments is equal to the sum of the first expansion amount of the first connection via during the edge expansion processing and the first expansion amount of the second connection via during the edge expansion processing; the movement distance during translation of the first-region influencing metal line segments located on the second side of the corresponding interconnection metal line included in the influencing metal line segments is equal to the sum of the second expansion amount of the first connection via during the edge expansion processing and the second expansion amount of the second connection via during the edge expansion processing; the movement distance during translation of the second-region influencing metal line segments located on the first side of the corresponding interconnection metal line included in the influencing metal line segments is equal to the first expansion amount of the first connection via during the edge expansion processing; the movement distance during translation of the second-region influencing metal line segments located on the second side of the corresponding interconnection metal line included in the influencing metal line segments is equal to the second expansion amount of the first connection via during the edge expansion processing. The movement distance during translation of the third-region influencing metal line segments located on the first side of the corresponding interconnection metal line included in the influencing metal line segments is equal to the first expansion amount of the second connection via during the edge expansion processing. The movement distance during translation of the third-region influencing metal line segments located on the second side of the corresponding interconnection metal line included in the influencing metal line segments is equal to the second expansion amount of the second connection via during the edge expansion processing.

To facilitate understanding, the following provides a detailed explanation using the original layout of metal lines and vias 20 shown in FIG. 7 as an example. The original layout of metal lines and vias 20 shown in FIG. 7 can be understood as an addition of another square via layer (i.e., the second square via layer 24) on the basis of the original layout of metal lines and vias 20 shown in FIG. 2. Specifically, as shown in FIGS. 7 and 8, in the original layout of metal lines and vias 20, the upper surface of the interconnection metal line 231B included in the second metal line layer 23 is connected to the connection via 221B included in the first square via layer 22, and the lower surface is connected to the connection via 241 included in the second square via layer 24. Furthermore, as shown in FIG. 8, when observing the first square via layer 22, the second metal line layer 23, and the second square via layer 24 from a top view, it can be seen that the projection of the connection via 221B on the horizontal plane (i.e., the plane perpendicular to the Z-axis in FIG. 8) overlaps with the projection of the connection via 241 on the horizontal plane. The connection via 221B and the connection via 241 have the same dimension in their respective width directions (i.e., the direction perpendicular to the extension direction of the interconnection metal line 231B), and the dimension of the connection via 221B along the extension direction of the interconnection metal line 231B is smaller than the dimension of the connection via 241 along the extension direction of the interconnection metal line 231B.

Specifically, as shown in FIG. 8, in the second metal line layer 23 where the interconnection metal line 231B is located, the influencing metal line segments corresponding to the connection via 221B and the connection via 241 (i.e., the influencing metal line segment A2, the influencing metal line segment A4, the influencing metal line segment C2, and the influencing metal line segment C4) include the first-region influencing metal line segments (i.e., the region influencing metal line segment A22 and the region influencing metal line segment C23) and the third-region influencing metal line segments (i.e., the region influencing metal line segment A21, the region influencing metal line segment A23, the region influencing metal line segment C21, and the region influencing metal line segment C23), but do not include the second-region influencing metal line segments. The region influencing metal line segment A22 belongs to both the influencing metal line segment A2 and the influencing metal line segment A4. The region influencing metal line segment C22 belongs to both the influencing metal line segment C2 and the influencing metal line segment C4, and the region influencing metal line segment A21, the region influencing metal line segment A23. The region influencing metal line segment C21 and the region influencing metal line segment C22 belong to the influencing metal line segment A4, the influencing metal line segment A4, the influencing metal line segment C4, and the influencing metal line segment C4, respectively.

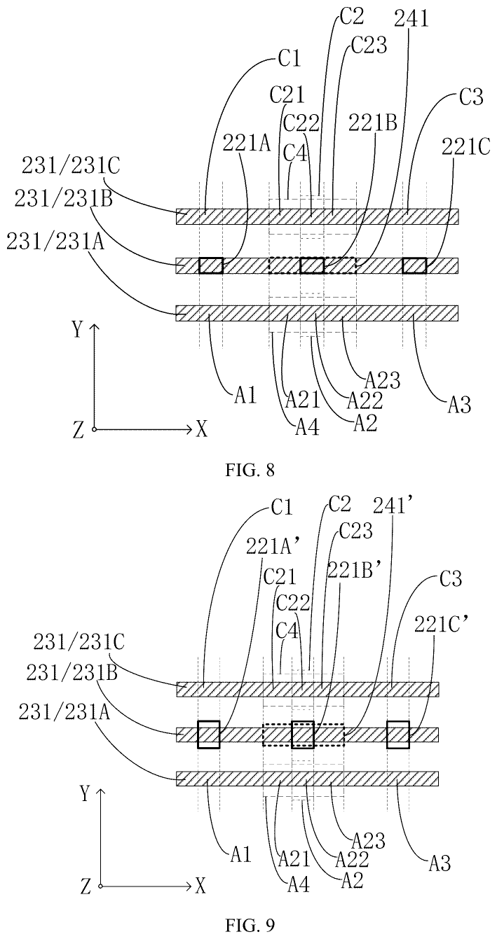

Specifically, as shown in FIGS. 8 and 9, after performing hole expansion processing on the connection via 221B in its corresponding width direction, the connection via 221B will become an enlarged connection via 221B′; after performing hole expansion processing on the connection via 241 in its corresponding width direction, the connection via 241 will become an enlarged connection via 241′. Moreover, the dimension expansion amount of the connection via 221 during the edge expansion processing is greater than the dimension expansion amount of the connection via 241 during the edge expansion processing. In other words, the dimension of the enlarged connection via 221B′ along the width direction corresponding to the connection via 221B is greater than the dimension of the enlarged connection via 241′ along the width direction corresponding to the connection via 241.

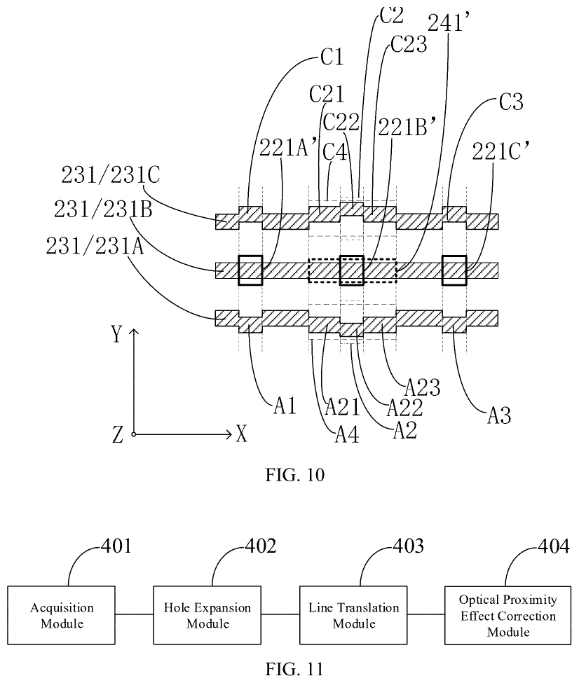

Next, as shown in FIGS. 8, 9, and 10, the first-region influencing metal line segments (i.e., the region influencing metal line segment A22 and the region influencing metal line segment C22) and the third-region influencing metal line segments (i.e., the region influencing metal line segment A21, the region influencing metal line segment A23, the region influencing metal line segment C21, and the region influencing metal line segment C23) can be translated by a certain distance in corresponding width directions (i.e., the direction perpendicular to the extension direction of the interconnection metal line 231B) away from the interconnection metal line 231B. The sum of the movement distances of the region influencing metal line segment A22 and the region influencing metal line segment C22 is equal to the sum of the dimension expansion amount of the connection via 221B during the edge expansion processing and the dimension expansion amount of the connection via 241 during the edge expansion processing. The sum of the movement distances of the region influencing metal line segment A21 and the region influencing metal line segment C21 is equal to the dimension expansion amount of the connection via 241 during the edge expansion processing, and the sum of the movement distances of the region influencing metal line segment A23 and the region influencing metal line segment C23 is equal to the dimension expansion amount of the connection via 241 during the edge expansion processing.

S104. performing optical proximity correction on the preprocessed layout of metal lines and vias to obtain a corrected layout of metal lines and vias.

Specifically, after obtaining the preprocessed layout of metal lines and vias, an optical proximity correction method (such as a conventional optical proximity correction method like the model-based optical proximity correction method) can be employed to correct the optical proximity effects of the preprocessed layout of metal lines and vias, which allows for the enlargement of the lithography process window while ensuring circuit connectivity, resulting in a corrected layout of metal lines and vias.

It should be noted that in this embodiment, the connection vias in the original layout of metal lines and vias are first enlarged, and the relevant influencing metal line segments in the original layout of metal lines and vias are appropriately moved. Subsequently, a conventional optical proximity correction method is used to correct the enlarged connection vias and the moved interconnection metal lines. In this way, the lithography process window for the interconnection metal lines and connection vias can be enlarged to a greater extent while meeting the requirements of circuit connectivity, thus it enhances the process feasibility of the interconnection metal lines and connection vias, improves product yield, and enables the technology node of the interconnection metal lines to be reduced (e.g., reduced to around 25 nm), thereby enhancing product competitiveness.

In some embodiments, after the above S104, that is, after obtaining the corrected layout of metal lines and vias, a photomask is fabricated based on the metal line and via patterns in the corrected layout of metal lines and vias. Then, lithography technology is used to fabricate the metal line and via patterns on the wafer, achieving the transfer of the designed original layout of metal lines and vias onto the wafer.

As can be seen from the above, the optical proximity effect correction method for layout of metal lines and vias provided in this embodiment first identifies, from the original layout of metal lines and vias, the connection vias that connect metal lines located in different layers, and the interconnection metal lines, influencing metal lines, and influencing metal line segments corresponding to the connection vias. The interconnection metal line is the metal line connected to the connection via, the influencing metal line is the metal line adjacent to the interconnection metal line along the width direction, the width direction is the direction perpendicular to the extension direction of the interconnection metal line within the plane of the layer where the interconnection metal line is located, and the influencing metal line segment is the projection region line segment of the connection via on the influencing metal line along the width direction. Then, the connection via is subjected to hole expansion processing along the width direction to form an enlarged connection via, and the influencing metal line segment is translated by a certain distance along the width direction away from the interconnection metal line, the movement distance is made to be equal to the dimension expansion amount of the connection via along the width direction. In this way, enlarging the connection via can increase the lithography process window for the interconnection metal line and the connection via, moving the interconnection metal line can make it less prone to bridge defects, and the limited movement amount of the interconnection metal line can make it less prone to defects such as necking and open circuit, thereby ensuring that when a subsequent optical proximity correction method is used to correct the enlarged connection via and the moved interconnection metal line, the lithography process window for the interconnection metal line and the connection via can be enlarged to a greater extent while meeting the requirements of circuit connectivity. Therefore, the process feasibility of the interconnection metal line and the connection via can be improved, the product yield can be increased, and the technology node of the interconnection metal line can be reduced (e.g., reduced to around 25 nm), thereby enhancing product competitiveness. Additionally, the optical proximity effect correction method for layout of metal lines and vias provided in this application is applicable to all layout of metal lines and vias, and thus has broad application prospects.

Based on the method described in the above embodiment, this embodiment will further describe the optical proximity effect correction device for layout of metal lines and vias to implement the method described in the above embodiment. Referring to FIG. 11, FIG. 11 specifically depicts the optical proximity effect correction device for layout of metal lines and vias provided in an embodiment of this application. The optical proximity effect correction device for layout of metal lines and vias includes: an acquisition module 401, a hole expansion module 402, a line translation module 403, and an optical proximity correction module 404. The acquisition module 401 is communicatively connected to the hole expansion module 402, the hole expansion module 402 is communicatively connected to the line translation module 403, and the line translation module 403 is communicatively connected to the optical proximity correction module 404. The functions of each module are as follows:
(1) Acquisition Module 401

The acquisition module 401 is configured to obtain an original layout of metal lines and vias, the original layout of metal lines and vias include at least two metal line layers and a square via layer connecting metal lines in different layers, and each metal line layer includes an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line, and a metal line adjacent to the interconnection metal line along the width direction in the metal line layer is defined as an influencing metal line, and the influencing metal line includes influencing metal line segment that refers to a projected line segment of the connection via on the influencing metal line along the width direction.

Specifically, the ratio of the dimension expansion amount of the connection via to the dimension of the connection via along the width direction can be α, where 0.5≤α≤0.75.
(2) Hole Expansion Module 402

The hole expansion module 402 is configured to, based on the original layout of metal lines and vias transmitted by the acquisition module 401, perform hole expansion processing on each connection via along the width direction to form an enlarged connection via, such that the dimension of the enlarged connection via along the width direction is greater than the width of the interconnection metal line, and a dimension of the enlarged connection via along the extension direction remains unchanged, and a dimension expansion amount of the connection via along the width direction is determined based on a current lithography process window.
(3) Line translation Module 403

The line translation module 403 is configured to, based on the original layout of metal lines and vias transmitted by the acquisition module 401 and the dimension expansion amount of the connection via along the width direction transmitted by the hole expansion module 402, translate each influencing metal line segment by a certain distance along the width direction along the direction away from the interconnection metal line. The movement distance is equal to the dimension expansion amount of the connection via along the width direction, thereby forming a preprocessed layout of metal lines and vias.

In some embodiments, when the hole expansion module 302 performs hole expansion processing on the connection via along the width direction to form an enlarged connection via, it may specifically execute the following: performing hole expansion processing on the connection via along the width direction toward both sides of the interconnection metal line by a first dimension expansion amount and a second dimension expansion amount, respectively. The sum of the first dimension expansion amount and the second dimension expansion amount is equal to the dimension expansion amount of the connection via.

Specifically, the first dimension expansion amount and the second dimension expansion amount may be equal.

Specifically, there may be an influencing metal line on each side of the interconnection metal line, namely a first influencing metal line and a second influencing metal line. The movement distance of the influencing metal line segment of the first influencing metal line is a first movement distance, and the movement distance of the influencing metal line segment of the second influencing metal line is a second movement distance. Moreover, the first movement distance may be equal to the first dimension expansion amount, and the second movement distance may be equal to the second dimension expansion amount.

In some embodiments, the upper surface of the interconnection metal line may be connected to a first connection via, and the lower surface of the interconnection metal line may be connected to a second connection via. The projection of the first connection via on the horizontal plane overlaps with the projection of the second connection via on the horizontal plane. The dimensions of the first connection via and the second connection via along the width direction may be the same, and the dimension of the first connection via along the extension direction may be smaller than the dimension of the second connection via along the extension direction.

Specifically, when the hole expansion module 402 performs hole expansion processing on the connection via along the width direction to form an enlarged connection via, it may specifically execute the following:
performing hole expansion processing on the first connection via along the width direction to form a first enlarged connection via, and performing hole expansion processing on the second connection via along the width direction to form a second enlarged connection via, and the dimension expansion amount of the first connection via is greater than that of the second connection via.

Specifically, the influencing metal line segments may include a first-region influencing metal line segment, a second-region influencing metal line segment, and a third-region influencing metal line segment. The first-region influencing metal line segment is the overlapping projection region line segment of the first connection via and the second connection via on the influencing metal line along the width direction. The second-region influencing metal line segment is the projection region line segment of only the first connection via on the influencing metal line along the width direction. The third-region influencing metal line segment is the projection region line segment of only the second connection via on the influencing metal line along the width direction.

Correspondingly, when the line translation module 403 translates the influencing metal line segments along the width direction away from the interconnection metal line, it may specifically execute the following: translating the first-region influencing metal line segment, the second-region influencing metal line segment, and the third-region influencing metal line segment respectively, the movement distance of the first-region influencing metal line segment is equal to the sum of the dimension expansion amount of the first connection via and the dimension expansion amount of the second connection via. The movement distance of the second-region influencing metal line segment is equal to the dimension expansion amount of the first connection via. The movement distance of the third-region influencing metal line segment is equal to the dimension expansion amount of the second connection via.

In some specific embodiments, the ratio of the dimension increase of the second connection via to that of the first connection via may be β, where 0.4≤β≤0.8.
(4) Optical Proximity Correction Module 404

The optical proximity correction module 404 is configured to perform optical proximity correction on the preprocessed layout of metal lines and vias transmitted by the line translation module 403 to obtain a corrected layout of metal lines and vias.

In specific implementation, each of the above modules may be implemented as an independent entity, or may be combined in any manner to be implemented as the same or several entities. For the specific implementation of each module, reference may be made to the foregoing method embodiments, which are not repeated here.

An embodiment of the present application further provides a computer-readable storage medium, where the computer-readable storage medium stores a computer program, and the computer program is suitable for being loaded by a processor to execute the method described in the foregoing embodiments.

Those skilled in the art can understand that all or part of the steps in the various methods of the above embodiments can be completed by instructions, or completed by instructing related hardware. The instructions can be stored in a computer-readable storage medium and loaded and executed by a processor.

To this end, an embodiment of the present application further provides a computer-readable storage medium. The computer-readable storage medium stores a computer program, and the computer program can be loaded by a processor to execute the steps of any optical proximity effect correction method for layout of metal lines and vias provided in the embodiments of the present application. For example, the computer program can execute the following steps:
obtaining an original layout of metal lines and vias, the original layout of metal lines and vias include at least two metal line layers and a square via layer connecting metal lines in different layers, and each metal line layer includes an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line, and a metal line adjacent to the interconnection metal line along the width direction in the metal line layer are defined as an influencing metal line, and the influencing metal line comprises influencing metal line segments that are projection region line segments of the connection via on the influencing metal line along the width direction;
performing hole expansion processing on each connection via along the width direction to form an enlarged connection via, such that a dimension of the enlarged connection via along the width direction is greater than the width of the interconnection metal line, and a dimension of the enlarged connection via along the extension direction remains unchanged, and a dimension expansion amount of the connection via along the width direction is determined based on a current lithography process window;
translating each influencing metal line segment along the width direction away from the interconnection metal line by a distance equal to the dimension expansion amount of the connection via along the width direction, to form a preprocessed layout of metal lines and vias; and
performing optical proximity correction on the preprocessed layout of metal lines and vias to obtain a corrected layout of metal lines and vias.

The specific implementation of each of the above operations can be referred to the previous embodiments, and will not be repeated here. The computer-readable storage medium may include: Read-Only Memory (ROM), Random Access Memory (RAM), magnetic disk, or optical disc, etc.

Since the computer program stored in the computer-readable storage medium can execute the steps of any optical proximity effect correction method for layout of metal lines and vias provided in the embodiments of the present application, it can achieve the beneficial effects that any optical proximity effect correction method for layout of metal lines and vias provided in the embodiments of the present application can achieve. For details, refer to the previous embodiments, and will not be repeated here.

The optical proximity effect correction method, device, and computer-readable storage medium for layout of metal lines and vias provided in the embodiments of the present application have been described in detail above. Specific examples are applied herein to explain the principles and implementation manners of the present application, and the descriptions of the above embodiments are only used to help understand the method and its core ideas of the present application. Meanwhile, for those skilled in the art, according to the ideas of the present application, there will be changes in specific implementation manners and application scopes. In conclusion, the content of this specification should not be construed as a limitation to the present application.

What is claimed is:

1. An optical proximity effect correction method for layout of metal lines and vias, comprising:
obtaining an original layout of metal lines and vias, wherein the original layout of metal lines and vias comprises at least two metal line layers and a square via layer connecting metal lines in different layers, each metal line layer comprises an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line; and a metal line adjacent to the interconnection metal line in the width direction i n the metal line layer is defined as an influencing metal line, and the influencing metal line comprises influencing metal line segment that refers to a projected line segment of the connection via on the influencing metal line along the width direction;
performing hole expansion processing on each connection via along the width direction to form an enlarged connection via, such that a dimension of the enlarged connection via along the width direction is greater than the width of the interconnection metal line, and a dimension of the enlarged connection via along the extension direction remains unchanged; and a dimension expansion amount of the connection via along the width direction is determined based on a current lithography process window;
performing translation processing on each influencing metal line segment along the width direction away from the interconnection metal line by a distance equal to the dimension expansion amount of the connection via along the width direction, to form a preprocessed layout of metal lines and vias; and
performing optical proximity correction on the preprocessed layout of metal lines and vias to obtain a corrected layout of metal lines and vias.

2. The method according to claim 1, wherein a ratio of the dimension expansion amount of the connection via to the dimension of the connection via along the width direction is α, where 0.5≤α≤0.75.

3. The method according to claim 1, wherein the hole expansion processing is performed by:
expanding the connection via by a first dimension expansion amount and a second dimension expansion amount respectively towards both sides of the interconnection metal line along the width direction, wherein a sum of the first dimension expansion amount and the second dimension expansion amount equals the dimension expansion amount of the connection via.

4. The method according to claim 3, wherein the first dimension expansion amount is equal to the second dimension expansion amount.

5. The method according to claim 3, wherein there is one influencing metal line on each side of the interconnection metal line, defined as a first influencing metal line and a second influencing metal line;
a translation distance of the influencing metal line segment on the first influencing metal line is defined as a first translation distance, and a translation distance of the influencing metal line segment on the second influencing metal line is defined as a second translation distance; and
the first translation distance is equal to the first dimension expansion amount, and the second translation distance is equal to the second dimension expansion amount.

6. The method according to claim 1, wherein an upper surface of the interconnection metal line is connected to a first connection via, and a lower surface of the interconnection metal line is connected to a second connection via; a projection of the first connection via on the horizontal plane overlaps with that of the second connection via, and the first connection via and the second connection via have identical dimensions along the width direction, and the first connection via has a smaller dimension along the extension direction than that of the second connection via;
the hole expansion processing is performed by:
expanding the first connection via along the width direction to form a first enlarged connection via, and expanding the second connection via along the width direction to form a second enlarged connection via; a dimension expansion amount of the first connection via is greater than that of the second connection via;
wherein the influencing metal line segment comprises a first-region influencing metal line segment, a second-region influencing metal line segment, and a third-region influencing metal line segment; the first-region influencing metal line segment is an overlapping projection region line segment of the first connection via and the second connection via on the influencing metal line along the width direction; the second-region influencing metal line segment is a projection region line segment of the first connection via on the influencing metal line along the width direction; and the third-region influencing metal line segment is a projection region line segment of the second connection via on the influencing metal line along the width direction;
the translation processing is performed by:
translating the first-region influencing metal line segment, the second-region influencing metal line segment, and the third-region influencing metal line segment, where a translation distance of the first-region influencing metal line segment is equal to a sum of dimension expansion amounts of the first connection via and the second connection via, a translation distance of the second-region influencing metal line segment is equal to the dimension expansion amount of the first connection via, and a translation distance of the third-region influencing metal line segment is equal to the dimension expansion amount of the second connection via.

7. The method according to claim 6, wherein a ratio of the dimension expansion amount of the second connection via to that of the first connection via is β, where 0.4≤β≤0.8.

8. A computer-readable storage medium, wherein the computer-readable storage medium stores a computer program adapted to be loaded by a processor to execute an optical proximity effect correction method for layout of metal lines and vias; wherein the method comprises:
obtaining an original layout of metal lines and vias, wherein the original layout of metal lines and vias comprises at least two metal line layers and a square via layer connecting metal lines in different layers, each metal line layer comprises an interconnection metal line connected to a connection via; in a plane of a layer where the interconnection metal line is located, a direction perpendicular to an extension direction of the interconnection metal line is defined as a width direction; a projection of the connection via on a horizontal plane falls within a projection of the interconnection metal line, and a dimension of the connection via along the width direction is equal to a width of the interconnection metal line; and a metal line adjacent to the interconnection metal line in the width direction i n the metal line layer is defined as an influencing metal line, and the influencing metal line comprises influencing metal line segment that refers to a projected line segment of the connection via on the influencing metal line along the width direction;
performing hole expansion processing on each connection via along the width direction to form an enlarged connection via, such that a dimension of the enlarged connection via along the width direction is greater than the width of the interconnection metal line, and a dimension of the enlarged connection via along the extension direction remains unchanged; and a dimension expansion amount of the connection via along the width direction is determined based on a current lithography process window;
performing translation processing on each influencing metal line segment along the width direction away from the interconnection metal line by a distance equal to the dimension expansion amount of the connection via along the width direction, to form a preprocessed layout of metal lines and vias; and
performing optical proximity correction on the preprocessed layout of metal lines and vias to obtain a corrected layout of metal lines and vias.
